(19) United States
(12) Patent Application Publication
(10) Pub. No.: US 2013/0098389 A1
(43) Pub. Date: Apr. 25, 2013

(54) Low Voltage Hair Iron

(71) Applicant: Izumi Uwano, Torrance, CA (US)

(72) Inventor: Izumi Uwano, Torrance, CA (US)

(21) Appl. No.: 13/279,611

(22) Filed: Oct. 24, 2011

(51) Int. Cl. A45D 1/04; H05K 13/00

(52) U.S. Cl. 132/269; 29/860

(57) ABSTRACT

A hair dressing device that utilizes low voltage from a pair of batteries to generate temperature needed for curling and straightening the hair comprises an upper body and a lower body, each having an outer side and an inner side. A heating plate is mounted on the inner side of the lower body facing the upper body. At least one heating element is mounted on the heating plate to generate heat utilizing high precision printing at high temperature. An insulating member is interposed between the at least one heating element and the heating plate to eliminate short circuit. The lower body is coupled to the upper body around a hinge section. A thermal sensor and a controller are incorporated in the hair dressing device to monitor and control the temperature of the heating plate. The hair dressing device can be connected and disconnected from power using an ON/OFF switch.

### CROSS-REFERENCE TO RELATED APPLICATIONS

Not Applicable.

### STATEMENT REGARDING FEDERALLY SPONSORED RESEARCH AND DEVELOPMENT

Not Applicable.

### FIELD OF THE INVENTION

This embodiment relates to the field of hair dressing devices and more particularly to an electric hair dressing device for curling and straightening hair using low voltage.

### DISCUSSION OF RELATED ART

Several types of hair-styling appliances are used by people for straightening and curling hair. These hair-styling appliances may include those that blow air onto the hair and those that contact hair with a heated surface. For the hair-dressing appliances utilizing a heated surface, the temperature of the heating surface is raised by transferring heat from a heating element attached separately from the heating plate. The voltage needed to heat the heating element is high resulting in high energy consumption.

The main problem with these hair-dressing appliances is that the heating plate is heated indirectly by contacting the heating element with the heating plate. This reduces the efficiency of thermal conduction and full advantage cannot be achieved. Another problem associated with the conventional hair dressing appliance is that there is no internal temperature control system. Thus the temperature of the heating element will vary uncontrollably resulting in hair damage. In the traditional manufacturing process of these hair-dressing appliances, the installation process is more complex and inefficient due to the arrangement of the heating plate and the heating element

U.S. Pat. No. 7,800,020 issued to Ceva on Sep. 21, 2010, discloses a heating plate for a hair straightening iron and a method for its manufacture. The heating plate consists of a case comprising two laminates made of insulating ceramic material. One of the laminates holds a band made of electrical conductor material with outer connections, while one of the laminates has a surface coated with a polished layer of material. The case of the heating plate has features to adapt to the base structure of the iron. The manufacturing process comprises: 1) preparing a ceramic powder which comprises the milling of dispersants and adding solvents; mixing with a binding agent; and adding plasticizer to control the viscosity of the result; 2) moulding and corresponding drying; 3) cuffing plates and screen-printing the resistor; 4) laminating the whole by pressure and cutting; 5) burning the binding agent and sintering; and 6) welding contact terminals, and coating with a polished layer. However the time needed by the hair iron to heat the heating plate after powering it on is high which results in high energy consumption.

U.S. Pat. Application No. 20080092915 entitled to Chan discloses a hair-styling apparatus comprising a handle and a hair-styling member with a transparent window. The hair curler is comprised of a handle and a styling member. The handle is positioned between the hair styling member and an electric cord for obtaining operating power. An on/off switch is located on the handle and comprises a sliding switch which is accessible from the outside of the handle for turning on or off the power supply. An indicator, such as a LED indicator, is located on the handle so that operating states of the hair curler can be shown. A pivotable clamping arm comprised of a hair clamping surface and a pivotable arm is provided at the middle portion of the apparatus. The hair styling member comprises a transparent tubular member with coated electrical heating substances distributed on the contact hair-styling surface. The heating substance can be coated at regions corresponding to the hair clamping member. By coating electric heating substances on selected portions of the hair styling member, only selected portions of the hair contact surface will be effectively heated; and the portion of the transparent tubular member which is not coated with the heating substances will not be directly heated so that risks of inadvertent harm to the scalp or other parts of a user can be alleviated. However the hair styling apparatus requires a power supply with high voltage output to raise the temperature of the transparent electrical heating substance.

In addition, U.S. Pat. No. 7,044,139 issued to Tong on May 16, 2006 provides a hair curling iron/straightener that includes a handle, a first elongated member connected with the handle and having a flat straightening surface; a heating element for heating the elongated member; a second elongated member pivotally connected relative to the first elongated member, with a second flat straightening surface for mating with the first flat straightening surface to straighten hair placed between and a second heating element for heating the second elongated member. This invention provides a hair curling iron and shaping tool that can selectively curl hair or otherwise shape hair in a different manner. However the appliance is not provided with an internal temperature control system which can result in a significant temperature variation of the heating plate.

Therefore there is a need for a hair-dressing appliance that uses low voltage to generate high temperature. Such a hair-dressing appliance would conducts heat effectively at high temperature. The appliance would be an easy to assemble appliance since the heating element can be directly attached to the heating plate. The appliance would be operated in low voltage using a pair of rechargeable batteries. In addition, the temperature sensor and the temperature controller would monitor and control the temperature of the heating element. The present invention accomplishes these objectives.

### SUMMARY OF THE INVENTION

The present invention is a hair dressing device for curling and straightening hair. The hair dressing device uses low voltage to generate high temperature. The hair dressing device comprises an upper body having an outer side and an inner side and a lower body having an outer side and an inner side. The hair dressing device requires only 2.4V to 12V to generate a high temperature of about 350 to 450 Fahrenheit. A heating plate is mounted on the inner side of the lower body facing the upper body. At least one heating element is mounted on the heating plate to transfer heat to the heating plate utilizing high precision printing at high temperature. An insulating member is interposed between the at least one heating element and the heating plate utilizing pattern printing to eliminate short circuit. The lower body is coupled to the upper body around a hinge section. The upper body and the lower body are thus molded to each other in such a manner as to permit motion only in one plane, backward and forward around the hinge section. The hinge section mainly comprises a copper inner shaft, a C-ring and a copper shaft.

A thermal sensor and a controller are incorporated in the hair dressing device to monitor and control the temperature of the heating plate. The hair dressing device can be connected and disconnected from power using an ON/OFF switch provided on the device. The hair dressing device can be powered from a pair of batteries. The pair of batteries may be a number of AA batteries or a rechargeable lithium battery. The at least one heating element is provided with a plurality of connection terminals to connect with the heating plate. The plurality of connection terminals are made by printing the electrodes made up of silver on to the at least one heating element. A plurality of leads is connected to the connection terminals using mechanical bonding by putting the plurality of leads through ‘U’ shaped electrode terminals.

The temperature of the at least one heating element is raised by powering the hair dressing device. The hair dressing device utilizes low voltage to raise the temperature of the at least one heating element. The heat from the at least one heating element is transferred to the heating plate through direct heat conduction which in turn transfers the heat to the hair strands in contact. A LED indicator is provided on the upper body of the hair dressing device to light by adjusting the temperature. The LED indicator is covered using a LED top cover incorporated in the upper body of the device.

The present invention provides a hair dressing device for curling and straightening hair at low voltage. The hair dressing device includes at least on heating element which is attached to the heating plate utilizing high precision printing. Such a hair dressing is operated in low voltage utilizing direct heat conduction at high temperature. Thus the hair dressing device can be powered from a pair of rechargeable batteries. Other features and advantages of the present invention will become apparent from the following more detailed description, taken in conjunction with the accompanying drawings, which illustrate, by way of example, the principles of the invention.

### DESCRIPTION OF THE DRAWINGS

FIG. 1 is a perspective view of a hair dressing device for curling and straightening hair in accordance with a preferred embodiment of the present invention;

FIG. 2A through 2D are perspective views of a lower body of the hair dressing device showing various patterns of at least one heating element;

FIG. 3 is a cross-sectional diagrammatic view of the lower body of the hair dressing device;

FIG. 4 is an exploded view of the hair dressing device of FIG. 1;

FIG. 5 is an operational flow chart of a method for manufacturing the hair dressing device in accordance with the preferred embodiment of the present invention; and

FIG. 6 is a perspective view of a hair dressing device for curling and straightening hair in accordance with an alternative embodiment of the present invention.

### DETAILED DESCRIPTION OF THE PREFERRED EMBODIMENT

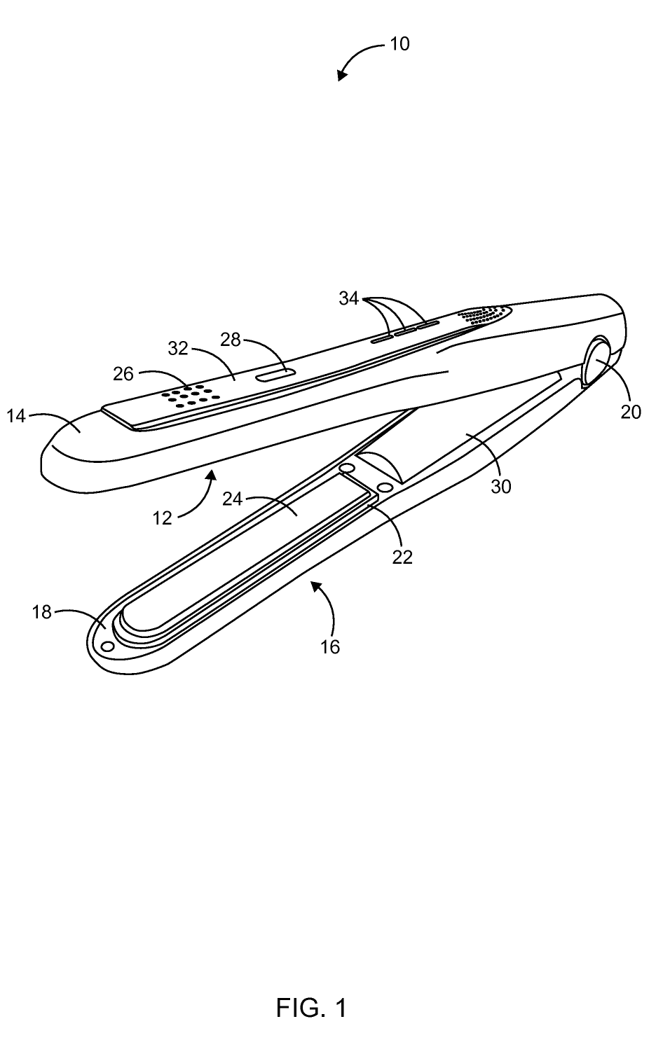

FIG. 1 is a perspective view of a hair dressing device 10 for curling and straightening hair. The hair dressing device 10 comprises an upper body 12 having an outer side 14 and an inner side (not shown) and a lower body 16 having an outer side (not shown) and an inner side 18. The lower body 16 is coupled to the upper body 12 around a hinge section 20. A heating plate 22 is mounted on the inner side 18 of the lower body 16 facing the upper body 12. At least one heating element 24 is mounted on the heating plate 22 to generate heat. A thermal sensor 26 and a controller (not shown) are incorporated in the hair dressing device 10 to monitor and control the temperature of the heating plate 22. The hair dressing device 10 can be connected and disconnected from power using an ON/OFF switch 28 provided on the device 10. The hair dressing device 10 requires only low voltage to generate high temperature The hair dressing device 10 can be powered from a pair of batteries 30.

The at least one heating element 24 can be operated at low voltage and can be powered from a pair of batteries 30. The pair of batteries 30 may be AA batteries or lithium batteries. The at least one heating element 24 is mounted on the heating plate 22 utilizing high precision printing at high temperature. The high precision printing results in wide area contact between the at least one heating element 24 and the heating plate 22 realizing efficient heat conduction and also reduces the energy consumption. Thus the heating plate 22 will have high temperature for long time and the power consumption is reduced. The heat from the at least one heating element 24 raises the temperature of the heating plate 22 through direct heat conduction which in turn transfers the heat to the hair strands in contact. The at least one heating element 24 may be made of ceramic resistance to withstand high temperature. The heating plate 22 is made of a heat conducting material like stainless steel.

The thermal sensor 26 mounted on the upper body 12 of the hair dressing device 10 monitors the operating temperature within the specified range. The controller (not shown) senses the power of the hair dressing device 10 to control the temperature of the at least one heating element 24 constantly and automatically. A LED indicator 34 is provided on the upper body 12 of the hair dressing device 10 to light by adjusting the temperature. The LED indicator 34 is covered using a LED top cover 32 incorporated in the upper body 12 of the device 10. The hair dressing device 10 may be used portably without any spatial restriction since the low voltage required to operate the hair dressing device 10 may be supplied by a pair of rechargeable batteries 30.

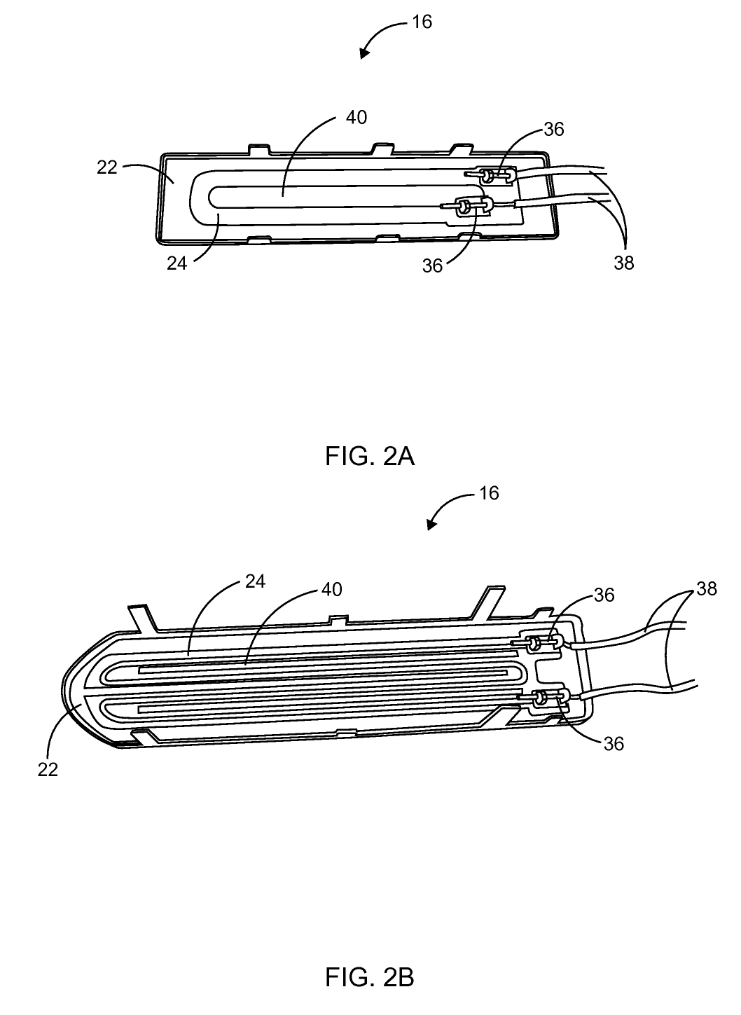

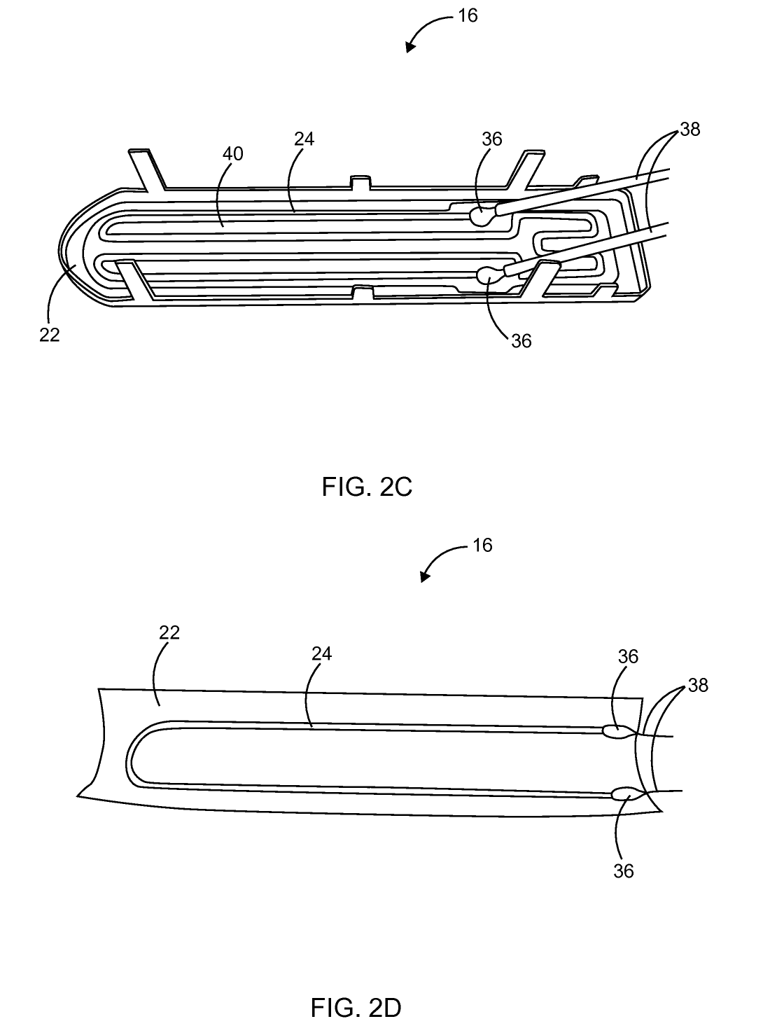

FIG. 2A through 2D are perspective views of a lower body 16 of the hair dressing device 10 showing various patterns of at least one heating element 24. The at least one heating element 24 is provided with a plurality of connection terminals 36 to connect with the heating plate 22. The plurality of connection terminals 36 are made by printing the electrodes made up of silver on to the at least one heating element 24. A plurality of leads 38 is connected to the plurality of connection terminals 36 using mechanical bonding by putting the plurality of leads 38 through ‘U’ shaped electrode terminals. An insulating member 40 is interposed between the at least one heating element 24 and the heating plate 22 utilizing pattern printing to eliminate short circuit. The insulating member 40 may be a dielectric.

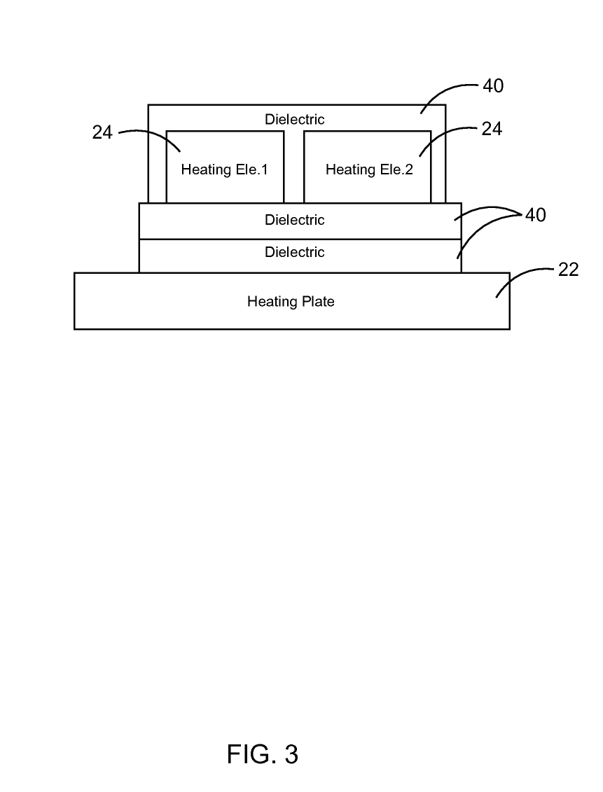

FIG. 3 is a cross sectional diagrammatic view of the lower body 16 of the hair dressing device 10. The hair dressing device 10 can be operated by low voltage using a pair of batteries 30. The heating plate 22 is coated with two layers of dielectric 40 to eliminate short circuiting. The at least one lightweight heating element 24 maintain high temperature and transfers the temperature to the heating plate 22 by efficient heat conduction. To achieve a sufficient amount of heat, printed ceramic resistance for large current is used. The at least one heating element 24 are printed on the heating plate 22 and the hair dressing device 10 may be produced in reproducible accurate process. The structure of the heating plate 22 is simplified and the numbers of the parts have been reduced.

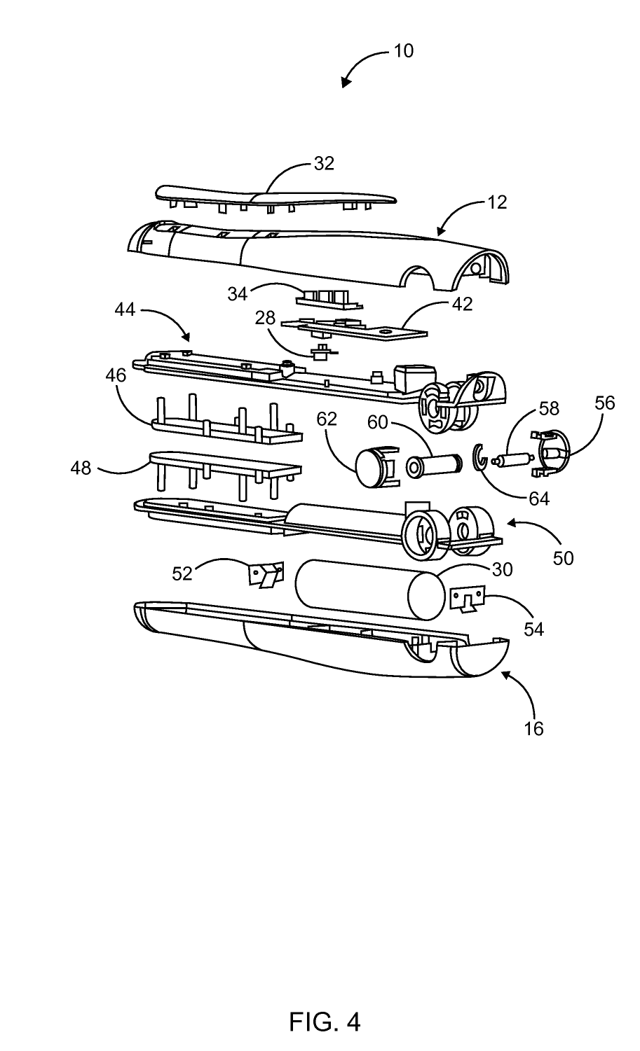

FIG. 4 is an exploded view of the hair dressing device 10 of FIG. 1. The LED top cover 32 incorporated in the upper body 12 covers the LED indicator 34. The electric circuit board 42 integrates all the electrical components needed to operate the hair dressing device 10. The lower body 16 and the upper body 12 are connected to each around the hinge section 20. The hinge section 20 mainly comprises a copper inner shaft 58, a C-ring 64 and a copper shaft 60. The whole hinge section 20 is incorporated inside a right hinge cover 56 and a left hinge cover 62. The upper body 12 and the lower body 16 are thus molded to each other in such a manner as to permit motion only in one plane, backward and forward around the hinge section 20. The hair dressing device 10 can be operated without using an external power cord. Instead, the hair dressing device 10 is powered using a pair of rechargeable batteries 30, hence the device 10 can be termed as a cordless hair dressing device 10. The heating plate 22 consisting of a lower heating plate 48 and an upper heating plate 46 is incorporated inside an inner cover 44 and a lower cover 50. The pair of rechargeable batteries 30 having positive battery terminal 52 and negative battery terminal 54 is incorporated inside the lower body 16.

Referring to FIG. 4, an operational flow chart of the method for manufacturing the hair dressing device in accordance with the preferred embodiment of the present invention is illustrated. The heating plate is cleaned before printing the at least one heating element on to the heating plate to remove the dirt and oil as shown in block 66. The cleaned heating plate is dried using a dryer as indicated at block 68. A first dielectric is printed on the surface of the heating plate as shown in block 70. After printing the insulator member on to the heating plate the whole arrangement is dried and baked at 850° Fahrenheit as indicated in block 72. A second dielectric is printed on the surface of the heating plate as indicated in block 74. The printed second dielectric is baked at 850° Fahrenheit as shown in block 76. At least one heating element is printed on the heating plate using precision printing as indicated in block 78. The at least one heating element is baked through the process of drying as shown in block 80. A plurality of connection terminals are affixed to at least one heating element by precision printing as indicated in block 82. A plurality of leads is connected to the connection terminals through welding as shown in block 84. Finally, as shown in block 86 a ceramic coating is made on the opposite side of the printed surface of the heating plate.

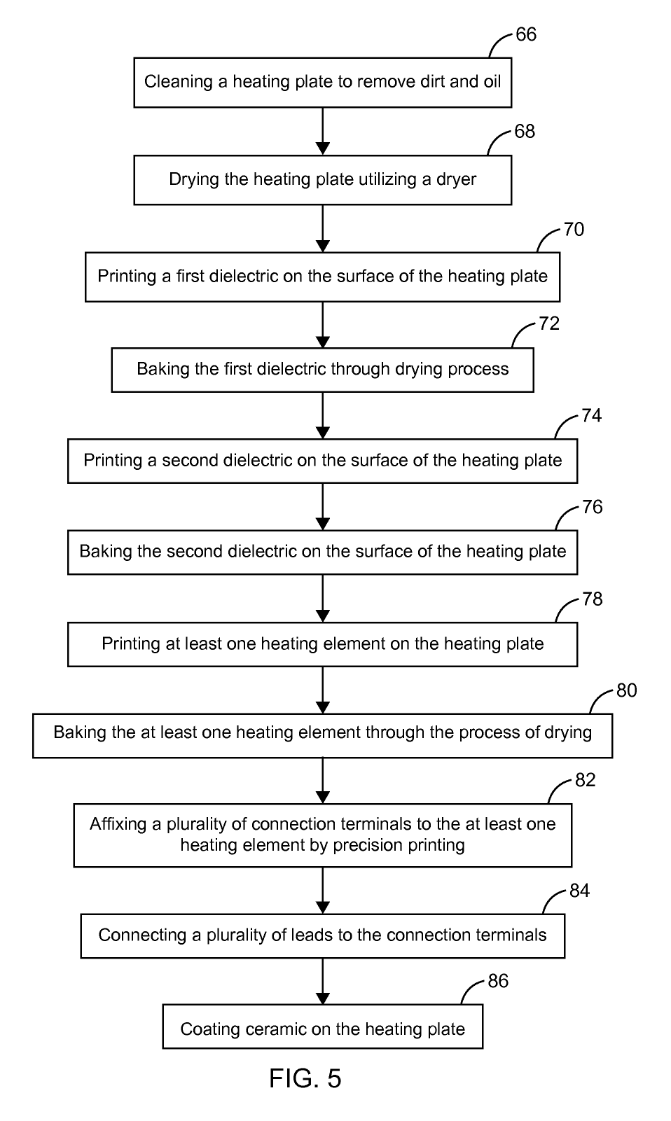

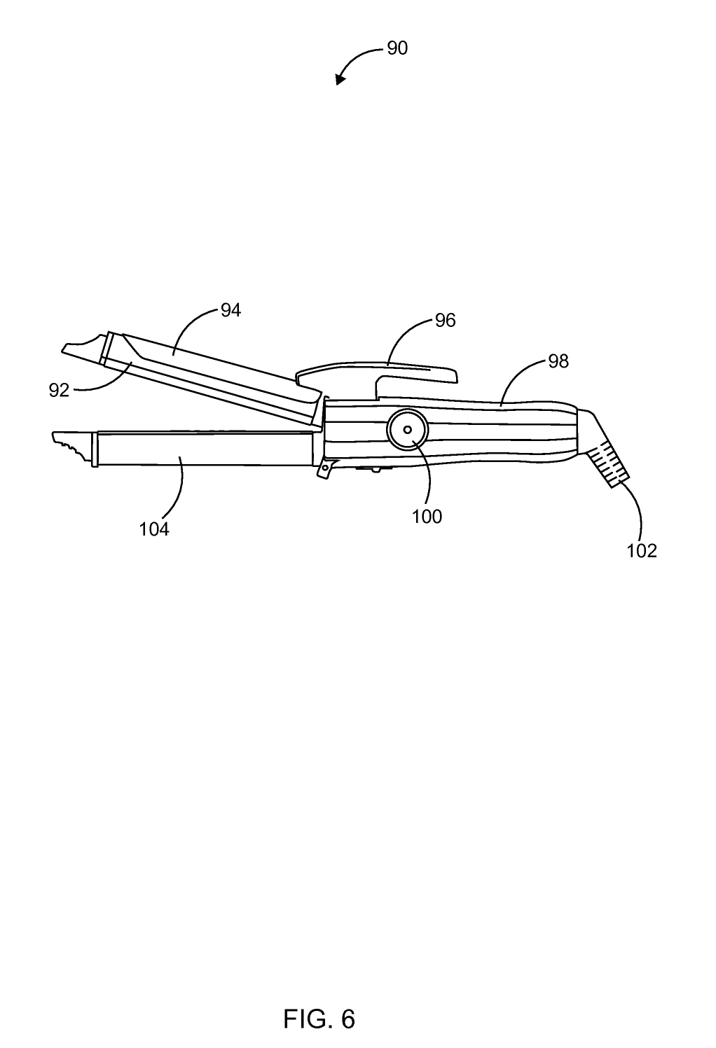

FIG. 5 is a perspective view of a hair dressing device 90 for curling and straightening hair in accordance with an alternative embodiment of the present invention. The hair dressing device 90 can be powered either by utilizing a pair of batteries (not shown) or by utilizing an external power supply by connecting the power cord 102. The hair dressing device 90 comprises an upper plate 92, a pushing plate 94, a pushing handle 96, a grip 98, a temperature adjustment dial 100, a power cord 102 and a lower plate 104. The pushing handle 96 moves the pushing plate 94 forward and backward. The grip 98 results in more safe handling of the hair dressing device 90. The temperature can be adjusted manually utilizing the temperature adjustment dial 100 provided on the body of the hair dressing device 90.

While a particular form of the invention has been illustrated and described, it will be apparent that various modifications can be made without departing from the spirit and scope of the invention. For example, the hair dressing device 10 may incorporate LCD indicators for displaying the operating temperature. The hair dressing device 10 may use high heat resistance material for at least one heating plate 24 to accomplish high temperature in low voltage. Likewise, the hair dressing device 10 may further include various hand grip 98 designs. Accordingly, it is not intended that the invention be limited, except as by the appended claims.

What is claimed is:

1. A hair dressing device comprising:
an upper body;
a lower body coupled to the upper body by a hinge section;
a heating plate mounted on the lower body;
at least one heating element being mounted on the heating plate;
a thermal sensor to monitor the temperature of the heating plate;
a controller to control the temperature of the heating plate;
an ON/OFF switch to connect/disconnect the hair dressing device from the power supply; and
a pair of batteries to power the hair dressing device;
is whereby low voltage received from the pair of batteries generates high temperature by the at least one heating element thereby transferring the temperature to the heating plate utilizing direct heat conduction from the at least one heating element.

2. The hair dressing device of claim 1 wherein the at least one heating element is mounted to the heating plate utilizing high precision printing at high temperature.

3. The hair dressing device of claim 2 wherein the high precision printing of the at least one heating element transfers high temperature to the heating plate.

4. The hair dressing device of claim 1 wherein the controller senses the power to control the temperature of the at least one heating element constantly and automatically.

5. The hair dressing device of claim 1 wherein the pair of batteries may be rechargeable.

6. The hair dressing device of claim 1 wherein the at least one heating element may be available in various shapes.

7. A hair dressing device comprising:
an upper body having an outer side and an inner side;
a lower body having an outer side and an inner side, the lower body being coupled to the upper body around a hinge section;
a heating plate mounted to the inner side of the lower body facing the upper body for transferring heat to hair strands;
at least one heating element mounted on the heating plate to generate heat;
a thermal sensor to monitor the temperature of the heating plate;
a controller to control the temperature of the heating plate;
an on/off switch to connect/disconnect the hair dressing device from a power supply; and
a pair of batteries to power the hair dressing device.

8. The hair dressing device of claim 7 wherein an LED top cover incorporated in the upper body includes an LED indicator to light by setting the temperature.

9. The hair dressing device of claim 7 wherein the at least one heating element may be ceramic resistance.

10. The hair dressing device of claim 7 wherein the at least one heating element is provided with a plurality of connection terminals.

11. The hair dressing device of claim 7 wherein a plurality of leads is connected to the plurality of connection terminals through mechanical bonding.

12. The hair dressing device of claim 7 wherein the heating plate is heated by connecting the plurality of leads of the at least one heating element to the heating plate.

13. The hair dressing device of claim 7 wherein an insulating member is interposed between the at least one heating element and the heating plate utilizing pattern printing to eliminate short circuit.

14. The hair dressing device of claim 7 wherein the insulating member may be a dielectric.

15. The hair dressing device of claim 7 wherein the high precision printing results in efficient heat conduction.

16. The hair dressing device of claim 7 wherein the heating plate may be made of stainless steel of corrosion resistance.

17. A method for manufacturing a hair dressing device which utilizes low voltage, the method comprising the steps of:
a) cleaning a heating plate to remove dirt and oil;
b) drying the heating plate utilizing a dryer;
c) printing a first dielectric on the surface of the heating plate;
d) baking the first dielectric through drying process;
e) printing a second dielectric on the surface of the heating plate;
f) baking the second dielectric on the surface of the heating plate;
g) printing at least one heating element on the heating plate;
h) baking the at least one of heating element through the process of drying;
i) affixing a plurality of connection terminals to the at least one heating element by precision printing;
j) connecting a plurality of leads to the connection terminals through welding; and
k) coating ceramic on the heating plate.

18. The method of claim 17 wherein the hair dressing device is manufactured through reproducible accurate process.

19. The method of claim 17 wherein the heating plate acquires a highest temperature of 450 Fahrenheit.

20. The method of claim 17 wherein the at least one heating element may be provided in a thickness of 0.15 mm.
